(19) United States
(12) Patent Application Publication
(10) Pub. No.: US 2024/0308893 A1
(43) Pub. Date: Sep. 19, 2024

(54) WATER REFINING APPARATUS AND METHOD OF MANUFACTURING WAFER

(71) Applicant: DISCO CORPORATION, Tokyo (JP)

(72) Inventors: Asahi NOMOTO, Tokyo (JP); Kazuya HIRATA, Tokyo (JP)

(21) Appl. No.: 18/604,676

(22) Filed: Mar. 14, 2024

(30) Foreign Application Priority Data
Mar. 15, 2023 (JP) 2023-040408

(51) Int. Cl. C02F 9/00; C02F 1/00; C02F 1/32; C02F 1/36; C02F 1/42

(52) U.S. Cl. CPC C02F 9/00; C02F 1/001; C02F 1/32; C02F 1/36; C02F 1/42; C02F 2209/22; C02F 2303/04

(57) ABSTRACT

A water refining apparatus for refining water flowing therein includes a filter for filtering the water to remove solid particles therefrom, a sterilizing unit disposed downstream of the filter and for irradiating the water with ultraviolet rays to sterilize the water, an ion exchange filter disposed downstream of the sterilizing unit and for performing an ion exchange on impurity ions contained in the water to remove impurities from the water, a deaerating unit for deaerating the water, and a measuring unit disposed downstream of the deaerating unit and for measuring a dissolved oxygen concentration in the water.

### BACKGROUND OF THE INVENTION

### Field of the Invention

The present invention relates to a water refining apparatus for refining water flowing therein and a method of manufacturing a wafer from an ingot.

### Description of the Related Art

In general, semiconductor device chips are manufactured from disk-shaped wafers. A disk-shaped wafer is fabricated by, for example, slicing a cylindrical ingot into a circular wafer blank with a wire saw and polishing a face side of the wafer blank to a mirror finish.

Specifically, when a wafer blank is cut from an ingot by a wire saw, the wafer blank has minute surface irregularities on its face side and is curved in its entirety, i.e., is warped. Therefore, wafer blanks thus sliced off often have their face sides polished to remove surface irregularities therefrom and planarize themselves.

Polishing a wafer blank produces swarf therefrom that is to be discarded, so that the wafer blank is thinned down by being polished. In view of the inevitable swarf attributable to polishing of wafer blanks, it is a general practice to slice semiconductor ingots into wafer blanks that are thicker than polished wafers from which semiconductor devices chips are to be manufactured.

Semiconductor ingots from which to manufacture semiconductor device chips are expensive. Therefore, providing wafers are fabricated from semiconductor ingots according to a method that involves polishing, semiconductor device chips manufactured from the wafers are liable to be expensive as well.

Monocrystalline silicon carbide (SiC) that has been expected as a material of power devices is high in hardness. Therefore, cutting a wafer blank from an ingot of monocrystalline SiC with a wire saw tends to be time-consuming and wear the wire saw quickly.

As a result, the cost of manufacturing wafers of monocrystalline SiC is likely to be high. To alleviate this difficulty, there has been proposed a method of manufacturing wafers from an ingot with a laser beam (see, for example, Japanese Patent Laid-open No. 2016-111143).

According to the proposed method, specifically, a laser beam whose wavelength is transmittable through the ingot is applied to the ingot while its focused spot is being positioned within the ingot, thereby forming a fragile layer including modified regions and cracks developed from the modified regions within the ingot. The ingot is then cleaved along the fragile layer, producing a wafer blank.

Furthermore, there has been proposed a method of cleaving the ingot along the fragile layer formed therein uses ultrasonic waves (see, for example, Japanese Patent Laid-open No. 2016-146446). According to the proposed method, specifically, while water is being supplied to an end face of the ingot, ultrasonic waves are propagated in the ingot through the water. Cracks developed in the ingot are further extended, cleaving the ingot along the fragile layer.

### SUMMARY OF THE INVENTION

However, when the ultrasonic waves are propagated in the ingot formed with the fragile layer through the water, a period of time required to cleave the ingot along the fragile layer tends to be long. Therefore, it is important to propagate ultrasonic waves efficiently to the ingot without attenuating the energy of the ultrasonic waves in the water.

It is therefore an object of the present invention to provide a water refining apparatus for supplying water capable of propagating ultrasonic waves efficiently therethrough and a method of manufacturing a wafer by cleaving an ingot along a fragile layer therein within a reduced period of time.

In accordance with an aspect of the present invention, there is provided a water refining apparatus for refining water flowing therein, including a filter for filtering the water to remove solid particles therefrom, a sterilizing unit disposed downstream of the filter and for irradiating the water with ultraviolet rays to sterilize the water, an ion exchange filter disposed downstream of the sterilizing unit and for performing an ion exchange on impurity ions contained in the water to remove impurities from the water, a deaerating unit for deaerating the water, and a measuring unit disposed downstream of the deaerating unit and for measuring a dissolved oxygen concentration in the water.

In the water refining apparatus according to the present invention, the measuring unit preferably measures the dissolved oxygen concentration by referring to an intensity of deep ultraviolet rays that have passed through the water. Furthermore, preferably, the deaerating unit is disposed downstream of the filter and upstream of the sterilizing unit, the measuring unit is disposed upstream of the ion exchange filter, and the sterilizing unit and the measuring unit share a deep ultraviolet irradiator.

Preferably, the water refining apparatus according to the present invention further includes a controller for adjusting operating conditions of the deaerating unit, in which, in a case where the dissolved oxygen concentration measured by the measuring unit exceeds a predetermined value, the controller adjusts the operating conditions to reduce the dissolved oxygen concentration.

Preferably, the water refining apparatus further includes a valve selectively switchable to a forward state in which it introduces the water that has passed through the measuring unit into a forward channel and a reverse state in which it introduces the water that has passed through the measuring unit into a reverse channel for the water going back to the deaerating unit, and a controller for adjusting the state of the valve, in which the controller switches the valve to the reverse state when the dissolved oxygen concentration measured by the measuring unit exceeds a predetermined value and switches the valve to the forward state when the dissolved oxygen concentration measured by the measuring unit is equal to or smaller than the predetermined value.

In the water refining apparatus according to the present invention, preferably, the deaerating unit and the measuring unit are disposed downstream of the filter and upstream of the sterilizing unit, or downstream of the sterilizing unit and upstream of the ion exchange filter, or downstream of the ion exchange filter.

In the water refining apparatus according to the present invention, preferably, the deaerating unit includes a chamber for storing the water therein, a decompressor for decompressing an inner space of the chamber, and an ultrasonic oscillator for applying ultrasonic waves to the water that has flowed into the chamber. Preferably, the ultrasonic oscillator oscillates ultrasonic waves at a frequency ranging from 0.1 to 1.0 MHz, and the decompressor decompresses the inner space of the chamber to a pressure of 0.2 atm or lower.

In addition, preferably, the deaerating unit deaerates the water such that the dissolved oxygen concentration in the water reaches 2.0 mg/L or lower.

Preferably, the water refining apparatus according to the present invention further includes a first pipe disposed upstream of the filter and the deaerating unit and connectable to a water discharge port of a water utilizing apparatus that utilizes the water to perform a processing operation, and a second pipe disposed downstream of the ion exchange filter and the measuring unit and connectable to a water supply port of the water utilizing apparatus.

Preferably, the water refining apparatus according to the present invention further includes a second filter disposed downstream of the ion exchange filter and for filtering the water to remove therefrom solid particles caused by the ion exchange filter, and a temperature regulating unit disposed downstream of the second filter and for regulating a temperature of the water.

Preferably, the water refining apparatus according to the present invention further includes a tank disposed upstream of the filter and for storing the water.

In accordance with another aspect of the present invention, there is provided a method of manufacturing a wafer from an ingot, including a fragile layer forming step of applying, to an ingot, a laser beam having a wavelength transmittable through the ingot while positioning a focused spot of the laser beam in the ingot at a depth from an end face thereof that corresponds to a thickness of the wafer, thereby forming a fragile layer including modified regions and cracks developed therefrom in the ingot, and after the fragile layer forming step, a cleaving step of propagating ultrasonic waves to the ingot through water refined by a water refining apparatus and supplied to the end face of the ingot, thereby further developing the cracks to cleave the ingot along the fragile layer, in which the water refining apparatus includes a filter for filtering the water to remove solid particles therefrom, a sterilizing unit disposed downstream of the filter and for irradiating the water with ultraviolet rays to sterilize the water, an ion exchange filter disposed downstream of the sterilizing unit and for performing an ion exchange on impurity ions contained in the water to remove impurities from the water, a deaerating unit for deaerating the water, and a measuring unit disposed downstream of the deaerating unit for measuring a dissolved oxygen concentration in the water.

In the method of manufacturing a wafer according to the present invention, the ingot is made of monocrystalline silicon carbide. Preferably, the end face lies not parallel to a c-plane of the monocrystalline silicon carbide, and the fragile layer forming step includes an irradiating step of irradiating the ingot with the laser beam while moving the focused spot of the laser beam and the ingot relatively to each other along a direction parallel to a crossing line along which the c-plane of the monocrystalline silicon carbide and the end face cross each other, and an indexing step of moving a position where the focused spot of the laser beam is to be formed and the ingot relatively to each other along a direction perpendicular to the crossing line, and the irradiating step and the indexing step are alternately performed repeatedly in the fragile layer forming step.

The water refining apparatus according to the present invention includes the deaerating unit for deaerating water. Therefore, the water supplied from the water refining apparatus contains oxygen dissolved at a reduced condensation, making it less liable to produce air bubbles, i.e., cavitation, due to the vaporization of oxygen even when ultrasonic waves are applied.

Stated otherwise, the water refined by and supplied from the water refining apparatus to the water utilizing apparatus is less likely to attenuate the energy of ultrasonic waves with the cavitation caused by the ultrasonic waves. Consequently, the water refining apparatus is able to provide water capable of propagating ultrasonic waves efficiently therethrough.

With the method of manufacturing a wafer according to the present invention, ultrasonic waves are propagated to the ingot with the fragile layer formed therein through the water supplied from the water refining apparatus according to the present invention. Therefore, the method makes it possible to propagate ultrasonic waves efficiently to the ingot, thereby reducing the period of time required to cleave the ingot along the fragile layer.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a block diagram schematically illustrating an example of a water refining apparatus;

FIG. 2 is a cross-sectional view, partly in block form, schematically illustrating an example of a deaerating unit;

FIG. 3 is a cross-sectional view, partly in block form, schematically illustrating another example of the deaerating unit;

FIG. 4 is a cross-sectional view, partly in block form, schematically illustrating an example of a measuring unit;

FIG. 5 is a block diagram schematically illustrating a water refining apparatus according to Modification 1;

FIG. 6 is a block diagram schematically illustrating a water refining apparatus according to Modification 2;

FIG. 7 is a block diagram schematically illustrating a water refining apparatus according to Modification 3;

FIG. 8 is a block diagram schematically illustrating a water refining apparatus according to Modification 4;

FIG. 9 is a block diagram schematically illustrating a water refining apparatus according to Modification 5;

FIG. 10A is a perspective view schematically illustrating an example of an ingot;

FIG. 10B is a front elevational view schematically illustrating the ingot depicted in FIG. 10A;

FIG. 11 is a flowchart schematically illustrating an example of a method of manufacturing a wafer from an ingot;

FIG. 12 is a perspective view schematically illustrating a manner in which a fragile layer forming step is carried out;

FIG. 13A is an enlarged fragmentary cross-sectional view schematically illustrating an ingot obtained after the fragile layer forming step;

FIG. 13B is a plan view schematically illustrating the ingot obtained after the fragile layer forming step; and

FIG. 14 is a cross-sectional view, partly in elevation, schematically illustrating a manner in which a cleaving step is carried out.

### DETAILED DESCRIPTION OF THE PREFERRED EMBODIMENT

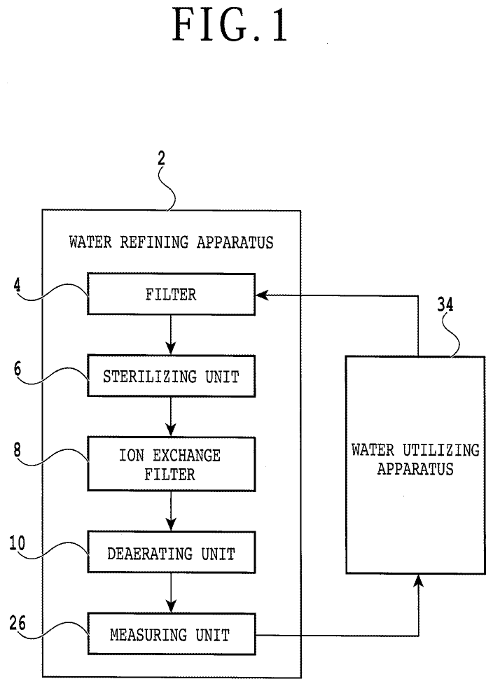

Preferred embodiments of the present invention will be described below with reference to the accompanying drawings. FIG. 1 schematically illustrates in block form an example of a water refining apparatus for refining water flowing therein. In FIG. 1, flow of water is indicated by solid-line arrows. The water refining apparatus, denoted by 2 in FIG. 1, has a filter 4 for filtering water to remove solid particles therefrom.

The filter 4 includes a hollow fiber membrane and/or a nonwoven fabric, for example. The solid particles removed from water by the filter 4 may be, for example, swarf produced from an ingot at a time at which a wafer is manufactured from the ingot. A filtered water pan, not depicted, for receiving the water that has passed through the filter 4 may be disposed downstream of the filter 4.

The water refining apparatus 2 may alternatively include a plurality of filters 4 disposed parallel to each other. If the water refining apparatus 2 has the plural filters 4, then the water refining apparatus 2 also has a plurality of pipes, not depicted, disposed upstream of and connected to the filters 4, respectively, for supplying water to the respective filters 4.

Moreover, a shared filtered water pan, not depicted, for receiving the water that has passed through the filters 4 may be disposed downstream of the filters 4. Valves, not depicted, for selectively supplying water to either one of the filters 4 and stopping supplying water to the other filters 4, i.e., filter selecting valves, may be disposed upstream of and connected to the filters 4.

In addition, a water pressure gage, not depicted, may be disposed upstream of and connected to the filter 4 or the filters 4, e.g., upstream of the filter selecting valves. The water pressure measured by the water pressure gage varies depending on clogging of the filter 4 that is currently supplied with water.

Therefore, by referring to the water pressure measured by the water pressure gage, it is possible to operate the filter selecting valves at an appropriate timing for replacing the filters 4 with new ones and/or changing the filter 4 to be supplied with water to a different filter 4.

The water refining apparatus 2 further includes a sterilizing unit 6 disposed downstream of the filter 4 or the filters 4 for irradiating the water with ultraviolet rays to sterilize the water. Specifically, the sterilizing unit 6 is supplied with water that has passed through the filter 4 or the filters 4 and hence contains solid particles having a reduced concentration.

The sterilizing unit 6 has a pipe, not depicted, for being supplied with water and an ultraviolet irradiator, not depicted, for irradiating water supplied to the pipe with ultraviolet rays. The pipe has a window made of a material through which the ultraviolet rays are transmittable, such as ultraviolet ray transmission glass, at a position aligned with an optical path of the ultraviolet rays emitted from the ultraviolet irradiator.

The pipe may be made in its entirety with the material through which the ultraviolet rays are transmittable. The ultraviolet irradiator includes an ultraviolet lamp, an ultraviolet light-emitting diode (LED), or the like, for example.

The sterilizing unit 6 sterilizes water flowing through the pipe with ultraviolet rays emitted from the ultraviolet irradiator and applied through the pipe to the water. The sterilizing unit 6 should preferably emit deep ultraviolet rays, particularly deep ultraviolet rays in a wavelength range from 250 to 260 nm, for enhanced sterilization.

Specifically, the sterilizing unit 6 should preferably have a deep ultraviolet irradiator capable of emitting deep ultraviolet rays, particularly deep ultraviolet rays in a wavelength range from 250 to 260 nm. The deep ultraviolet irradiator includes a deep ultraviolet lamp, a deep ultraviolet LED, or the like, for example.

Between the filter 4 or the filters 4 and the sterilizing unit 6, there may be connected a tank, not depicted, for storing water that has passed through the filter 4 or the filters 4 and a pump, not depicted, for delivering the water stored in the tank to the sterilizing unit 6. Moreover, the tank may have a drain valve for discarding the stored water without delivering it to the sterilizing unit 6.

An ion exchange filter 8 for performing an ion exchange on impurity ions contained in water to remove impurities from the water is disposed downstream of the sterilizing unit 6. The ion exchange filter 8 includes a cation exchange resin and/or an anion exchange resin, for example.

The cation exchange resin may be, for example, a strongly acidic cation exchange resin having a sulfonate group or a slightly acidic cation exchange resin having a carboxylic acid group. The anion exchange resin may be, for example, a strongly basic anion exchange resin having a quaternary amine or a slightly basic anion exchange resin having primary through tertiary amines.

The impurities to be removed from the water by the ion exchange filter 8 may be, for example, of calcium (Ca), sodium (Na), chlorine (Cl), or the like. An ion exchange water pan, not depicted, for receiving the water that has passed through the ion exchange filter 8 may be disposed downstream of the ion exchange filter 8.

Alternatively, a plurality of ion exchange filters 8 may be disposed parallel to each other downstream of the sterilizing unit 6. If the ion exchange filters 8 are included, then a plurality of pipes, not depicted, connected to the ion exchange filters 8, respectively, for supplying water to the respective ion exchange filters 8 are disposed upstream of the ion exchange filters 8.

Moreover, a shared ion exchange water pan, not depicted, for receiving the water that has passed through the ion exchange filters 8 may be disposed downstream of the ion exchange filters 8. Valves, not depicted, for selectively supplying water to either one of the ion exchange filters 8 and stopping supplying water to the other ion exchange filters 8, i.e., ion exchange filter selecting valves, may be disposed upstream of and connected to the ion exchange filters 8.

In addition, a detector, not depicted, for detecting a concentration of impurities contained in water may be disposed downstream of the ion exchange filter 8 or the ion exchange filters 8, e.g., downstream of the shared ion exchange water pan. The detector may be, for example, a conductivity meter, a total dissolved solids (TDS) meter, or the like.

A value measured by the detector varies depending on the ion exchange capability of the ion exchange filter 8 that is currently supplied with water. Therefore, by referring to the value measured by the detector, it is possible to operate the ion exchange filter selecting valves at an appropriate timing for replacing the ion exchange filters 8 with new ones and/or changing the ion exchange filter 8 to be supplied with water to a different ion exchange filter 8.

A deaerating unit 10 for deaerating water is disposed downstream of the ion exchange filter 8 or the ion exchange filters 8. Specifically, the deaerating unit 10 is supplied with water that has passed through the ion exchange filter 8 or the ion exchange filters 8 and hence contains impurities having a reduced concentration.

For efficient propagation of ultrasonic waves, the deaerating unit 10 should preferably achieve a dissolved oxygen concentration of 2.0 mg/L or lower, for example, in water. A pump, not depicted, for delivering water to the deaerating unit 10 may be connected between the ion exchange filter 8 or the ion exchange filters 8 and the deaerating unit 10.

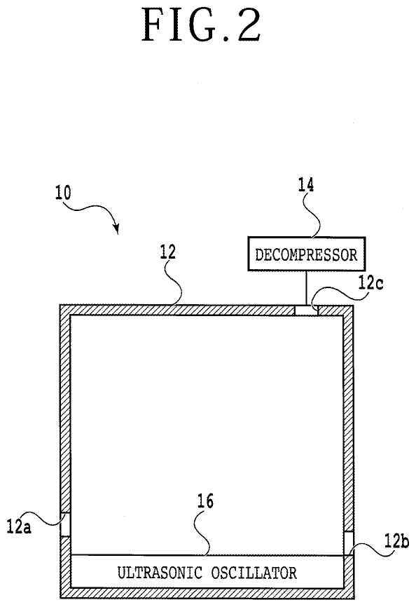

FIG. 2 schematically illustrates an example of the deaerating unit 10 in cross section, partly in block form. The deaerating unit 10 illustrated in FIG. 2 includes a chamber 12 for storing water therein, a decompressor 14 for decompressing an inner space of the chamber 12, and an ultrasonic oscillator 16 for applying ultrasonic waves to the water that has flowed into the chamber 12.

The chamber 12 has an inlet port 12a defined in a side panel thereof for introducing water into the chamber 12 and an outlet port 12b defined in another side panel thereof for discharging water out of the chamber 12. The chamber 12 also has an air discharge port 12c defined in an upper panel thereof. The decompressor 14 includes a vacuum pump, not depicted, or the like and is held in fluid communication with the air discharge port 12c through a duct, not depicted, or the like. The ultrasonic oscillator 16 includes an ultrasonic vibrator, not depicted, or the like and is mounted on a lower panel of the chamber 12.

The deaerating unit 10 illustrated in FIG. 2 operates as follows: While water is being stored in the chamber 12, the decompressor 14 is actuated to decompress the inner space of the chamber 12 to a pressure of 0.2 atm or lower, and the ultrasonic oscillator 16 is actuated to oscillate ultrasonic wavers at a frequency ranging from 0.1 to 1.0 MHz, for example. The water in the chamber 12 is now cavitated, and vaporized oxygen or the like is discharged from the water. In other words, the water in the chamber 12 is deaerated.

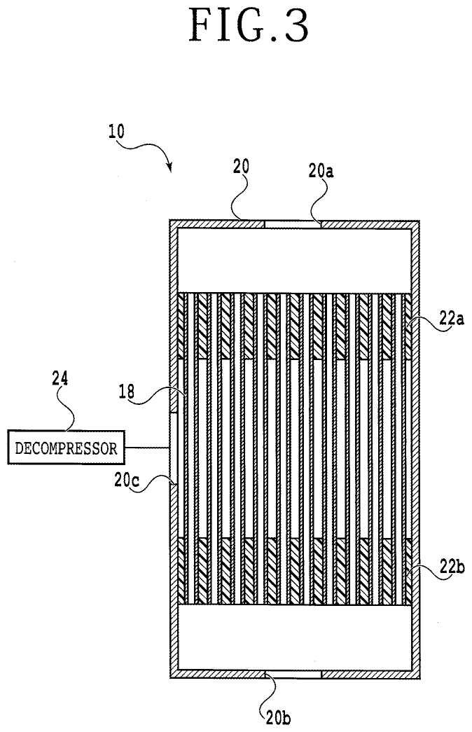

FIG. 3 schematically illustrates another example of the deaerating unit 10 in cross section, partly in block form. The deaerating unit 10 illustrated in FIG. 3 includes a plurality of hollow fiber membranes 18, a case 20 accommodating the hollow fiber membranes 18 therein, a pair of seal members 22a and 22b demarcating inner spaces in the case 20 and secured respectively to upper and lower end portions of the hollow fiber membranes 18, and a decompressor 24 for decompressing the inner space, i.e., an intermediate inner space, that is positioned between the seal members 22a and 22b among the inner spaces of the case 20.

The hollow fiber membranes 18 have respective upper end faces exposed in the inner space, i.e., an upper inner space, that is positioned above the seal member 22a among the inner spaces of the case 20. Similarly, the hollow fiber membranes 18 have respective lower end faces exposed in the inner space, i.e., a lower inner space, that is positioned below the seal member 22b among the inner spaces of the case 20. Therefore, the upper and lower inner spaces are held in fluid communication with each other through the hollow fiber membranes 18.

The case 20 has an inlet port 20a defined in an upper panel thereof for introducing water into the case 20 and an outlet port 20b defined in a lower panel thereof for discharging water out of the case 20. The case 20 also has an air discharge port 20c defined in a side panel thereof that is vertically positioned between the seal members 22a and 22b. The decompressor 24 includes a vacuum pump, not depicted, or the like and is held in fluid communication with the air discharge port 20c through a duct, not depicted, or the like.

The deaerating unit 10 illustrated in FIG. 3 operates as follows: While water is flowing in the hollow fiber membranes 18, the decompressor 24 is actuated to decompress the intermediate inner space of the case 20 to a pressure of 0.5 atm or lower, for example. The oxygen or the like dissolved in the water is vaporized and discharged from the water through the hollow fiber membranes 18. In other words, the water in the case 20 is deaerated.

As illustrated in FIG. 1, the water refining apparatus 2 further includes a measuring unit 26 disposed downstream of the deaerating unit 10 for measuring a dissolved oxygen concentration in the water. The measuring unit 26 is supplied with the water that has been deaerated by the deaerating unit 10. A pump, not depicted, for delivering the water to the measuring unit 26 may be connected between the deaerating unit 10 and the measuring unit 26.

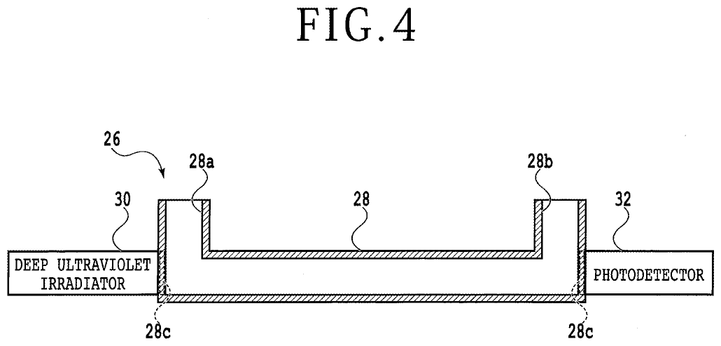

FIG. 4 schematically illustrates an example of the measuring unit 26 in cross section, partly in block form. The measuring unit 26 illustrated in FIG. 4 includes a U-shaped pipe 28, a deep ultraviolet irradiator 30 for irradiating water flowing in the pipe 28 with deep ultraviolet rays in a wavelength range from 250 to 260 nm, for example, and a photodetector 32 for detecting deep ultraviolet rays that have passed through the water flowing in the pipe 28.

The pipe 28 has an inlet port 28a defined in an end thereof for introducing water into the pipe 28 and an outlet port 28b defined in another end thereof for discharging water out of the pipe 28. The pipe 28 has a window 28c made of a material through which deep ultraviolet rays are transmittable, such as deep ultraviolet ray transmission glass, at a position aligned with the optical path of the deep ultraviolet rays emitted from the deep ultraviolet irradiator 30 to the photodetector 32. The other portion of the pipe 28 than the window 28c should preferably be made of a material capable of absorbing the deep ultraviolet rays, such as metal, in order to prevent stray light from occurring.

The deep ultraviolet irradiator 30 includes a deep ultraviolet lamp, a deep ultraviolet LED, or the like. The photodetector 32 includes a photodiode and the like. The deep ultraviolet irradiator 30 and the photodetector 32 are disposed in confronting relation to each other across the window 28c. The part of the pipe 28 that is positioned between the deep ultraviolet irradiator 30 and the photodetector 32 is of a hollow cylindrical shape having a length in the range from 400 to 600 mm, typically of 500 mm, and an inside diameter ranging from 20 to 40 mm, typically of 30 mm.

The measuring unit 26 measures the dissolved oxygen concentration in the water supplied to the pipe 28 by referring to an intensity of deep ultraviolet rays that have passed through the water in the pipe 28. Specifically, the measuring unit 26 operates as follows: While the part of the pipe 28 that is positioned between the deep ultraviolet irradiator 30 and the photodetector 32 is being filled with water, the deep ultraviolet irradiator 30 is actuated to irradiate the water with deep ultraviolet rays through the window 28c.

The photodetector 32 now detects deep ultraviolet rays which intensity reflects the dissolved oxygen concentration in the water. As a result, the measuring unit 26 can measure the dissolved oxygen concentration in the water.

As illustrated in FIG. 1, the water refining apparatus 2 is connected to a water utilizing apparatus 34 that utilizes water to perform a processing operation, so that water will be circulated between the water refining apparatus 2 and the water utilizing apparatus 34. Specifically, the water refining apparatus 2 has a pipe, i.e., a first pipe, positioned most upstream that is connected to a water discharge port of the water utilizing apparatus 34 and a pipe, i.e., a second pipe, positioned most downstream that is connected to a water supply port of the water utilizing apparatus 34.

The water refining apparatus 2 refines water discharged from the water utilizing apparatus 34 and supplies the refined water back to the water utilizing apparatus 34. The water utilizing apparatus 34 may be, for example, an ultrasonic apparatus that propagates ultrasonic waves to an ingot through water.

A pump, not depicted, for delivering water utilized by and discharged from the water utilizing apparatus 34 to the water refining apparatus 2 may be connected between the first pipe of the water refining apparatus 2 and the water discharge port of the water utilizing apparatus 34. Similarly, a pump, not depicted, for delivering water refined by and discharged from the water refining apparatus 2 to the water utilizing apparatus 34 may be connected between the second pipe of the water refining apparatus 2 and the water supply port of the water utilizing apparatus 34.

The water refining apparatus 2 described above includes the deaerating unit 10 for deaerating water. Therefore, the water refined by and supplied from the water refining apparatus 2 to the water utilizing apparatus 34 has a reduced dissolved oxygen concentration. Even when ultrasonic waves are applied to the water in the water utilizing apparatus 34, the water is less liable to be cavitated.

Stated otherwise, the water refined by and supplied from the water refining apparatus 2 to the water utilizing apparatus 34 is less likely to attenuate the energy of ultrasonic waves with the cavitation caused by the ultrasonic waves. Consequently, the water refining apparatus 2 is able to provide water capable of propagating ultrasonic waves efficiently therethrough.

The water refining apparatus 2 described above represents only an example of water refining apparatus according to the present invention, and the water refining apparatus according to the present invention is not limited to the water refining apparatus 2. For example, the water refining apparatus according to the present invention may have the deaerating unit 10 and the measuring unit 26 downstream of the filter 4 or the filters 4 and upstream of the sterilizing unit 6 or downstream of the sterilizing unit 6 and upstream of the ion exchange filter 8 or the ion exchange filters 8.

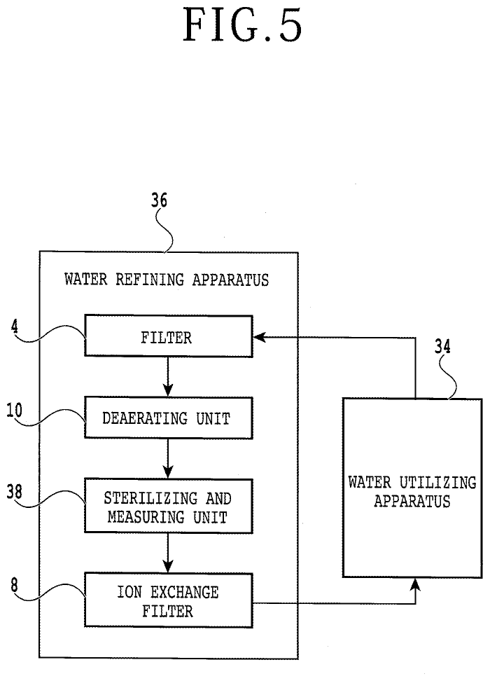

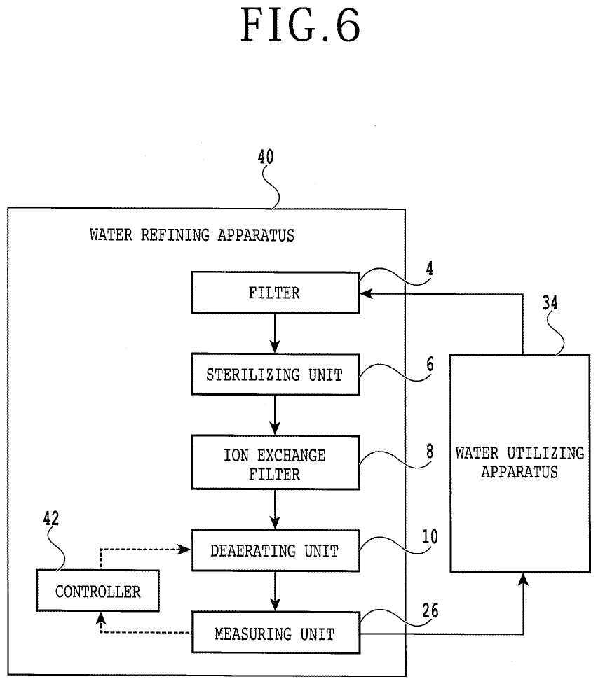

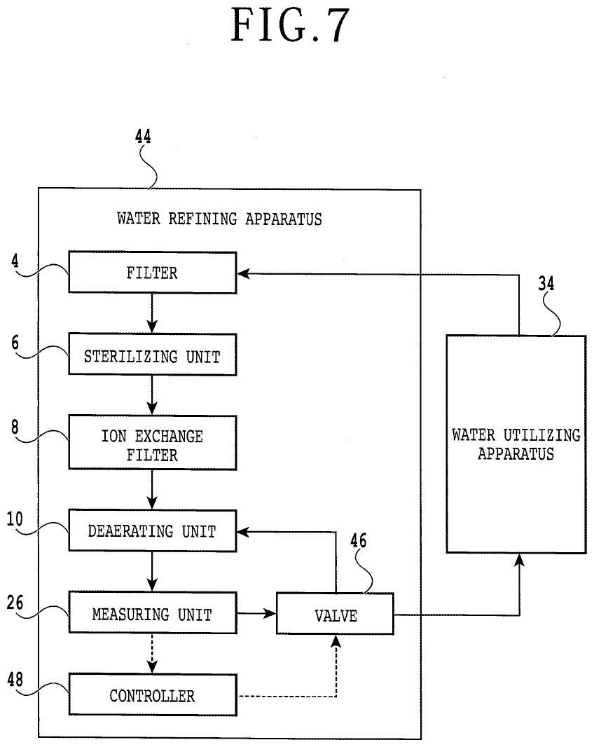

The water refining apparatus according to the present invention may be either one of water refining apparatuses illustrated in FIGS. 5 through 9. FIGS. 5 through 9 schematically illustrates in block form water refining apparatuses according to Modifications 1 through 5, respectively. In each of FIGS. 5 through 9, the flow of water is indicated by the solid-line arrows. In each of FIGS. 6 and 7, signals are sent and received as indicated by the dotted-like arrows.

The water refining apparatus, denoted by 36 in FIG. 5, includes a filter 4 or a plurality of filters 4, a deaerating unit 10 disposed downstream of the filter 4 or the filters 4, a sterilizing and measuring unit 38 disposed downstream of the deaerating unit 10, and an ion exchange filter 8 or a plurality of ion exchange filters 8 disposed downstream of the sterilizing and measuring unit 38.

The sterilizing and measuring unit 38 is of the same structure as the measuring unit 26 illustrated in FIG. 4, for example. Specifically, in the water refining apparatus 36, the deep ultraviolet rays emitted from the deep ultraviolet irradiator 30 are used not only to measure the dissolved oxygen concentration in the water supplied to the pipe 28, but also to sterilize the water. Accordingly, the water refining apparatus 36 may be rephrased to include a sterilizing unit and a measuring unit that share the deep ultraviolet irradiator 30.

The water refining apparatus 36 thus configured is preferable to the water refining apparatus 2 illustrated in FIG. 1 in that the former is simpler in structure and less expensive to manufacture than the latter. The water refining apparatus 2 illustrated in FIG. 1 is preferable to the water refining apparatus 36 in that it includes the sterilizing unit 6 and the measuring unit 26 that have respective structural details customized to their requirements.

The water refining apparatus, denoted by 40 in FIG. 6, includes, in addition to the components of the water refining apparatus 2 illustrated in FIG. 1, a controller 42 for adjusting operating conditions of the deaerating unit 10. The controller 42 includes a processor and a memory. The processor is in a form of a central processing unit (CPU), for example.

The memory includes a volatile memory such as a dynamic random access memory (DRAM) or a static random access memory (SRAM) and a nonvolatile memory such as a solid state drive (SSD), i.e., a NAND-type flash memory, or a hard disk drive (HDD), i.e., a magnetic storage device.

The memory stores various pieces of information (data, programs, and the like) used by the processor. The memory also stores, for example, a predetermined value to be used for comparison with the dissolved oxygen concentration in water that has been measured by the measuring unit 26. Specifically, the predetermined value represents a threshold value used to determine whether water is capable of propagating ultrasonic waves efficiently or not, and is set to 2.0 mg/L, for example.

The water refining apparatus 40 operates as follows: In a case where the dissolved oxygen concentration in water that has been measured by the measuring unit 26 is in excess of the predetermined value stored in the memory, the processor reads a program from the memory, the program for changing operating conditions of the deaerating unit 10 in order to reduce the dissolved oxygen concentration, and executes the read program.

With the deaerating unit 10 illustrated in FIG. 2, the dissolved oxygen concentration in water can be reduced by increasing the output level of ultrasonic waves emitted from the ultrasonic oscillator 16, for example. With the deaerating unit 10 illustrated in FIG. 3, the dissolved oxygen concentration in water can be reduced by increasing the speed at which air is discharged from the intermediate inner space of the case 20 by the decompressor 24, for example. Consequently, if the dissolved oxygen concentration in water that has been measured by the measuring unit 26 exceeds the predetermined value stored in the memory, then the processor changes operating conditions of the deaerating unit 10 in such a manner as to increase the output level of ultrasonic waves emitted and/or to increase the speed at which air is discharged, for example.

The water refining apparatus 40 thus configured is preferable to the water refining apparatus 2 illustrated in FIG. 1 in that it is able to provide water capable of propagating ultrasonic waves efficiently therethrough. The water refining apparatus 2 illustrated in FIG. 1 is preferable to the water refining apparatus 40 in that the former is simpler in structure and less expensive to manufacture than the latter.

The water refining apparatus, denoted by 44 in FIG. 7, includes, in addition to the components of the water refining apparatus 2 illustrated in FIG. 1, a valve 46 disposed downstream of the measuring unit 26 and a controller 48 for adjusting the state of the valve 46.

The valve 46 can selectively be switched by the controller 48 to a forward state in which it introduces the water that has passed through the measuring unit 26 into a forward channel leading to the water utilizing apparatus 34 and a reverse state in which it introduces the water that has passed through the measuring unit 26 into a reverse channel going back to the deaerating unit 10. The controller 48 includes a processor and a memory that are similar to those of the controller 42 illustrated in FIG. 6.

The water refining apparatus 44 operates as follows: In a case where the dissolved oxygen concentration in water that has been measured by the measuring unit 26 is in excess of the predetermined value stored in the memory, the processor of the controller 48 reads a program from the memory for switching the valve 46 to the reverse state. In a case where the dissolved oxygen concentration in water that has been measured by the measuring unit 26 is equal to or smaller than the predetermined value stored in the memory, the processor of the controller 48 reads a program from the memory for switching the valve 46 to the forward state.

The water refining apparatus 44 thus configured is preferable to the water refining apparatus 2 illustrated in FIG. 1 in that it is able to provide water capable of propagating ultrasonic waves efficiently therethrough. The water refining apparatus 2 illustrated in FIG. 1 is preferable to the water refining apparatus 44 in that the former is simpler in structure and less expensive to manufacture than the latter.

The controller 48 of the water refining apparatus 44 may adjust not only the state of the valve 46, but also operating conditions of the deaerating unit 10, as with the controller 42 illustrated in FIG. 6. The water refining apparatus 44 with the controller 48 thus modified is preferable as it is able to provide, with better accuracy, water capable of propagating ultrasonic waves efficiently therethrough.

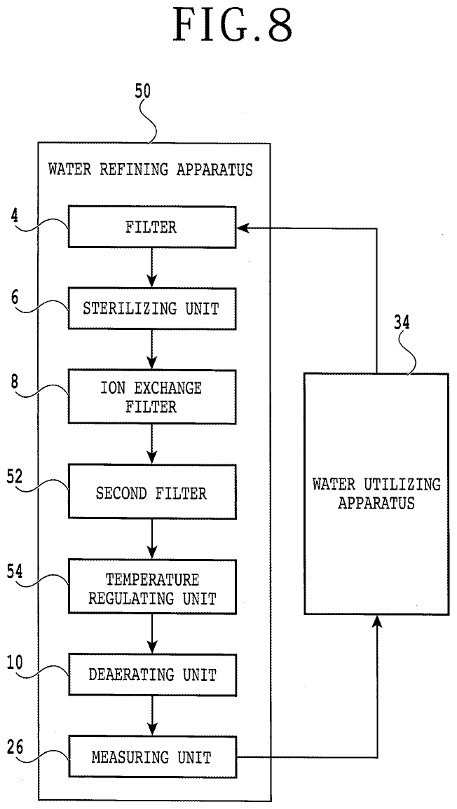

The water refining apparatus, denoted by 50 in FIG. 8, includes, in addition to the components of the water refining apparatus 2 illustrated in FIG. 1, a second filter 52 disposed downstream of the ion exchange filter 8 or the ion exchange filters 8, and a temperature regulating unit 54 disposed downstream of the second filter 52 and upstream of the deaerating unit 10.

The second filter 52 includes a hollow fiber membrane and/or a nonwoven fabric, for example, and filters water to remove therefrom solid particles caused by the ion exchange filter 8 or the ion exchange filters 8. The solid particles removed from the water by the second filter 52 may be, for example, debris of the cation exchange resin and/or the anion exchange resin that has been separated from the ion exchange filter 8 or the ion exchange filters 8. A second filtered water pan, not depicted, for receiving the water that has passed through the second filter 52 may be disposed downstream of the second filter 52.

The water refining apparatus 50 may alternatively include a plurality of second filters 52 disposed parallel to each other. If the water refining apparatus 50 has the plural second filters 52, then the water refining apparatus 50 also has a plurality of pipes, not depicted, disposed upstream of and connected to the second filters 52, respectively, for supplying water to the respective second filters 52.

Moreover, a shared second filtered water pan, not depicted, for receiving the water that has passed through the second filters 52 may be disposed downstream of the second filters 52. Valves, not depicted, for selectively supplying water to either one of the second filters 52 and stopping supplying water to the other second filters 52, i.e., second filter selecting valves, may be disposed upstream of and connected to the second filters 52.

In addition, a second water pressure gage, not depicted, may be disposed upstream of and connected to the second filter 52 or the second filters 52, e.g., upstream of the second filter selecting valves. The water pressure measured by the second water pressure gage varies depending on the clogging of the second filter 52 that is currently supplied with water.

Therefore, by referring to the water pressure measured by the second water pressure gage, it is possible to operate the second filter selecting valves at an appropriate timing for replacing the second filters 52 with new ones and/or changing the second filter 52 to be supplied with water to a different second filter 52.

The temperature regulating unit 54 has, for example, a pipe and a cooler for cooling the pipe. The part of the pipe that is close to the cooler includes a cooling region made of a material of high thermal conductivity, such as metal, for example. Alternatively, the pipe may be made in its entirety of a material of high thermal conductivity. The cooler includes a Peltier device, for example.

The temperature regulating unit 54 operates as follows: While water is flowing through the pipe, the cooler cools the water through the pipe to a temperature in the range from 0° C. or more to 30° C. or less. In order to make the water less liable to cavitate, the temperature regulating unit 54 should regulate the temperature of the water preferably in the range from 0° C. or more to 20° C. or less, and most preferably in the range from 0° C. or more to 10° C. or less.

The water refining apparatus 50 thus configured is preferable to the water refining apparatus 2 illustrated in FIG. 1 in that it can further reduce the density of solid particles included in the water and is able to provide water capable of propagating ultrasonic waves more efficiently therethrough. The water refining apparatus 2 illustrated in FIG. 1 is preferable to the water refining apparatus 50 in that the former is simpler in structure and less expensive to manufacture than the latter.

Moreover, the water refining apparatus 50 may include a pump, not depicted, for delivering water downstream in at least one location between the ion exchange filter 8 or the ion exchange filters 8 and the second filter 52, between the second filter 52 or the second filters 52 and the temperature regulating unit 54, or between the temperature regulating unit 54 and the deaerating unit 10.

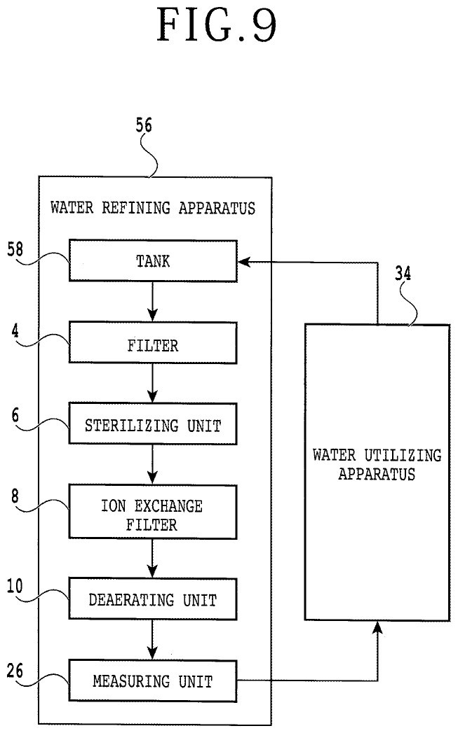

The water refining apparatus, denoted by 56 in FIG. 9, includes, in addition to the components of the water refining apparatus 2 illustrated in FIG. 1, a tank 58 disposed upstream of the filter 4 or the filters 4. The tank 58 stores the water discharged from the water utilizing apparatus 34. The tank 58 may have a drain valve for discarding the stored water without delivering it to the filter 4 or the filters 4.

The water refining apparatus 56 thus configured is preferable to the water refining apparatus 2 illustrated in FIG. 1 in that it is more convenient to use. The water refining apparatus 2 illustrated in FIG. 1 is preferable to the water refining apparatus 56 in that the former is simpler in structure and less expensive to manufacture than the latter. The water refining apparatus 56 may include a pump, not depicted, for delivering the water stored in the tank 58 to the filter 4 or the filters 4.

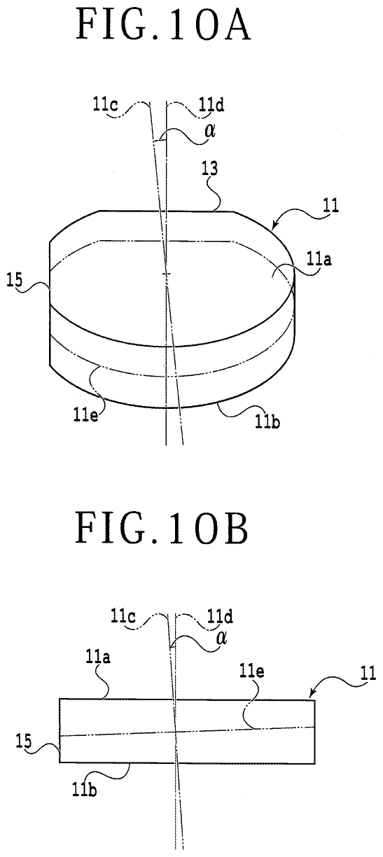

The water supplied from the water refining apparatus 2, 36, 40, 44, 50, or 56 is used by the water utilizing apparatus 34 when a wafer blank is manufactured from an ingot. FIG. 10A schematically illustrates an example of ingot in perspective, and FIG. 10B schematically illustrates the ingot depicted in FIG. 10A in front elevation.

The ingot, denoted by 11 in FIGS. 10A and 10B, is shaped as a cylinder made of monocrystalline SiC having a face side (end face) 11a and a reverse side 11b that lie generally parallel to each other. The ingot 11 is fabricated by way of epitaxial growth, for example.

In order to minimize lattice defects in the ingot 11, the ingot 11 is fabricated such that the c-axis 11c of monocrystalline SiC is slightly inclined to a line 11d normal to the face side 11a and the reverse side 11b, i.e., the c-plane 11e of the monocrystalline SiC lies not parallel to the face side 11a and the reverse side 11b.

The angle (off-angle) α formed between the c-axis 11c and the line 11d is in the range from 1° to 6°, typically of 4°. In FIGS. 10A and 10B, only one c-plane 11e is depicted for illustrative purposes. However, there are a number of c-planes 11e spaced at predetermined intervals between the face side 11a and the reverse side 11b of the ingot 11.

The ingot 11 has two flat surfaces representing the crystal orientation of the monocrystalline SiC on its outer circumferential edge, i.e., a primary orientation flat 13 and a secondary orientation flat 15. The primary orientation flat 13 is longer than the secondary orientation flat 15.

The secondary orientation flat 15 lies parallel to a crossing line along which the c-plane 11e of monocrystalline SiC and the face side 11a or the reverse side 11b cross each other. The ingot 11 may be free of one or both of the primary orientation flat 13 and the secondary orientation flat 15.

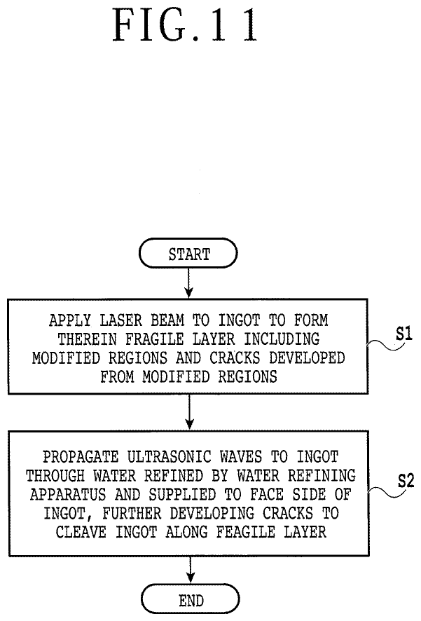

FIG. 11 is a flowchart schematically illustrating an example of a method of manufacturing a wafer blank from the ingot 11. According to the method, a laser beam is applied to the ingot 11 to form therein a fragile layer that includes modified regions and cracks developed from the modified regions (fragile layer forming step S1).

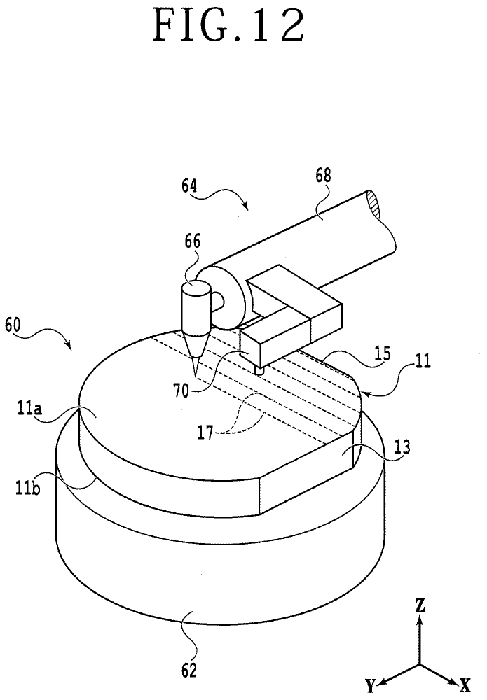

FIG. 12 schematically illustrates a manner in which the fragile layer forming step S1 is carried out in perspective. In FIG. 12, an X-axis indicated by an arrow X and a Y-axis indicated by an arrow Y extend horizontally perpendicularly to each other in a horizontal plane, and a Z-axis indicated by an arrow Z extends vertically perpendicularly to the X-axis and the Y-axis.

The fragile layer forming step S1 is carried out by a laser processing apparatus 60. The laser processing apparatus 60 has a disk-shaped holding table 62 for holding the ingot 11 thereon. The holding table 62 has a generally flat, circular upper surface as a holding surface where a porous plate is exposed.

The porous plate is fluidly connected to a suction source, not depicted, such as an ejector through a communication channel, not depicted, defined in the holding table 62. When the suction source is actuated, it generates and transmits a suction force through the communication channel to a space near the holding surface of the holding table 62. Therefore, when the suction source is actuated while the ingot 11 is being placed on the holding surface of the holding table 62, the ingot 11 is held under the suction force on the holding surface of the holding table 62.

The holding table 62 is operatively coupled to a rotating mechanism, not depicted, including a pulley and an electric motor. When the rotating mechanism is actuated, it rotates the holding table 62 about a straight axis extending through the center of the holding surface generally parallel to the Z-axis.

The holding table 62 is also operatively coupled to a horizontally moving mechanism, not depicted, including a ball screw and an electric motor, for example. When the horizontally moving mechanism is actuated, it moves the holding table 62 horizontally along the X-axis and/or the Y-axis.

The laser processing apparatus 60 further includes a laser beam applying unit 64 that has a head 66 disposed above the holding table 62. The head 66 is mounted on a distal end of a joint 68 extending along the Y-axis. The head 66 houses therein an optical system including a condensing lens and a mirror, whereas the joint 68 houses therein an optical system including a mirror and/or a lens.

The joint 68 has a proximal end, not depicted, operatively coupled to a vertically moving mechanism, not depicted, including a ball screw, an electric motor, and the like, for example. When the vertically moving mechanism is actuated, it moves the head 66 and the joint 68 along the Z-axis.

The laser beam applying unit 64 has a laser oscillator, not depicted, having a laser medium of neodymium-doped yttrium aluminum garnet (Nd:YAG), for example, for emitting a pulsed laser beam having a wavelength of 1064 nm or 1342 nm, for example, that is transmittable through the ingot 11.

The pulsed laser beam emitted from the laser oscillator is guided by the optical system housed in the joint 68 to travel to the head 66. The pulsed laser beam that has reached the head 66 passes through the condensing lens and is applied to the ingot 11 held on the holding surface of the holding table 62.

An image capturing unit 70 for capturing an image of the ingot 11 held on the holding surface of the holding table 62 is mounted on a side of the joint 68 adjacent to the head 66. The image capturing unit 70 has, for example, a light source such as an LED, an objective lens, and an image capturing element such as a charge-coupled-device (CCD) image sensor or a complementary-metal-oxide-semiconductor (CMOS) image sensor, all not depicted.

The laser processing apparatus 60 carries out the fragile layer forming step S1 as follows: First, the ingot 11 with the face side 11a facing upwardly is placed on the holding table 62 such that the center of the reverse side 11b of the ingot 11 and the center of the holding surface of the holding table 62 are aligned with each other. Then, the suction source fluidly connected to the porous plate of the holding table 62 is actuated to hold the ingot 11 under suction on the holding surface of the holding table 62.

Then, the image capturing unit 70 captures an image of the face side 11a of the ingot 11. On the basis of the captured image or the like, the rotating mechanism operatively coupled to the holding table 62 is actuated to turn the holding table 62 to direct the secondary orientation flat 15 parallel to the X-axis. Then, the horizontally moving mechanism is actuated to move the holding table 62 along the X-axis until the head 66 is positioned slightly off the ingot 11 radially outwardly from the outer circumferential edge thereof.

Thereafter, the vertically moving mechanism is actuated to move the head 66 along the Z-axis until the focused spot of the pulsed laser beam emitted from the head 66 is positioned in the ingot 11 at a depth from the face side 11a thereof that corresponds to the thickness of a wafer blank to be manufactured from the ingot 11. Then, the horizontally moving mechanism is actuated to move the holding table 62 along the X-axis relatively to the laser beam applying unit 64 to apply the pulsed laser beam emitted from the head 66 to the ingot 11 from one end to the other of the ingot 11 along the X-axis.

Specifically, the pulsed laser beam is applied to the ingot 11 while the focused spot of the pulsed laser beam and the ingot 11 are being moved relatively to each other along a direction parallel to the crossing line along which the c-plane 11e of the monocrystalline SiC of the ingot 11 and the face side 11a cross each other (irradiating step).

Then, the horizontally moving mechanism is actuated to move, i.e., index, the holding table 62 along the Y-axis relatively to the laser beam applying unit 64 by a predetermined distance. In other words, the position where the focused spot of the pulsed laser beam is to be formed in the ingot 11 and the ingot 11 are moved relatively to each other along a direction perpendicular to the crossing line (indexing step).

The irradiating step and the indexing step are alternately performed repeatedly until the pulsed laser beam is applied to the ingot 11 entirely over the face side 11a thereof. In this manner, a plurality of modified regions 17 extending along the X-axis are formed entirely in the ingot 11.

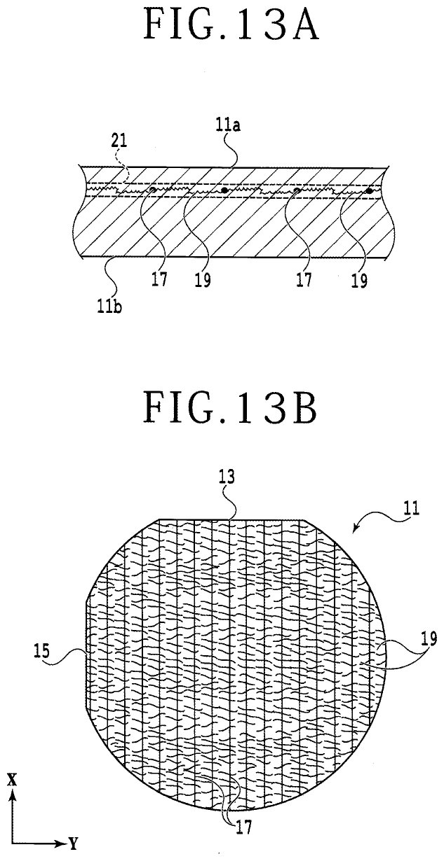

FIG. 13A schematically illustrates the ingot 11 after the fragile layer forming step S1 in enlarged fragmentary cross section. FIG. 13B schematically illustrates the ingot 11 after the fragile layer forming step S1 in plan.

When the modified regions 17 are formed in the ingot 11 in the fragile layer forming step S1, cracks 19 are developed along the c-plane 11e from the modified regions 17. The modified regions 17 and the cracks 19 thus formed jointly make up a fragile layer 21 in the ingot 11. Then, the fragile layer forming step S1 is completed.

After the fragile layer forming step S1, while the water refined by the water refining apparatus 2, 36, 40, 44, 50, or 56 is being supplied to the face side 11a of the ingot 11, ultrasonic waves are propagated to the ingot 11 through the supplied water, further developing the cracks 19 to cleave the ingot 11 along the fragile layer 21 (cleaving step S2).

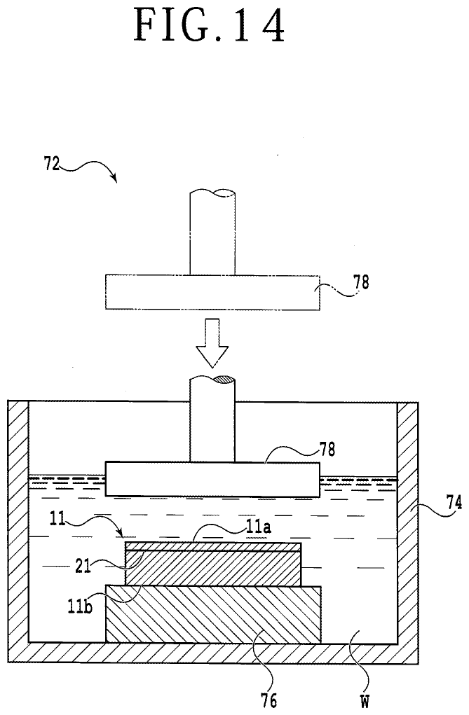

FIG. 14 schematically illustrates a manner in which the cleaving step S2 is carried out in cross section, partly in elevation. The cleaving step S2 is carried out by an ultrasonic apparatus 72, for example. The ultrasonic apparatus 72 has a water receptacle 74 capable of storing the water, denoted by W, supplied from the water refining apparatus 2, 36, 40, 44, 50, or 56. The water receptacle 74 accommodates therein a table 76 on which the ingot 11 can be placed while being immersed in the water W.

The ultrasonic apparatus 72 further has an ultrasonic oscillator 78 including an ultrasonic vibrator. The ultrasonic oscillator 78 is operatively coupled to a moving mechanism, not depicted, including a ball screw and an electric motor. When the moving mechanism is actuated, it moves the ultrasonic oscillator 78 selectively between a drive position in which its distal-end surface is held in contact with the water W stored in the water receptacle 74 and a retracted position in which its distal-end surface is held out of contact with the water W.

The ultrasonic apparatus 72 carries out the cleaving step S2 as follows: First, the water W refined by the water refining apparatus 2, 36, 40, 44, 50, or 56 is stored in the water receptacle 74. Then, the moving mechanism is actuated to bring the ultrasonic oscillator 78 into the retracted position. Thereafter, the ingot 11 with the face side 11a facing upwardly is placed on the table 76.

The moving mechanism is actuated to bring the ultrasonic oscillator 78 into the drive position. Then, the ultrasonic oscillator 78 is energized to oscillate ultrasonic waves. The ultrasonic waves are propagated through the water W to the ingot 11. When the ultrasonic waves are applied to the ingot 11, the cracks 19 formed in the fragile layer forming step S1 are further developed, cleaving the ingot 11 along the fragile layer 21 to produce a wafer blank from the ingot 11.

With the method of manufacturing a wafer as described above, the ultrasonic waves are propagated to the ingot 11 with the fragile layer 21 formed therein through the wager W supplied from the water refining apparatus 2, 36, 40, 44, 50, or 56. The method makes it possible to propagate the ultrasonic waves efficiently to the ingot 11, reducing a period of time required to cleave the ingot 11 along the fragile layer 21.

FIG. 14 illustrates the cleaving step S2 carried out while the ingot 11 is immersed in its entirety in the water W. However, it is not necessary to immerse the ingot 11 in its entirety in the water W in the cleaving step S2. The ultrasonic apparatus 72 may have, for example, a nozzle, not depicted, disposed in the vicinity of the ultrasonic oscillator 78 for supplying the water W to the face side 11a of the ingot 11, rather than immersing the ingot 11 in its entirety in the water W.

In the cleaving step S2, while the nozzle is supplying the water W to the face side 11a of the ingot 11, the ultrasonic oscillator 78 may be energized to oscillate ultrasonic waves to cleave the ingot 11 along the fragile layer 21, producing a wafer blank from the ingot 11.

The structural and methodical details of the above embodiment may be modified and changed without departing from the scope of the invention.

### EXAMPLES

An examination was conducted on examples to ascertain a relation between values of the dissolved oxygen concentration in the water and values of the period of time required to cleave ingots along fragile layers formed thereon by propagating ultrasonic waves to the ingots through the water. In the examination, when the ingots were cleaved, ultrasonic waves having a frequency of 25 kHz were applied to the water at 20° C.

Table 1 below illustrates results of the examination.

TABLE 1

| DISSOLVED OXYGEN | REQUIRED PERIOD OF |
|---|---|
| CONCENTRATION (mg/L) | TIME (s) |
| 8.1 | 1352 |
| 6.55 | 1223 |
| 5.8 | 1123 |
| 5.48 | 1082 |
| 4.97 | 1002 |
| 4.08 | 815 |
| 3.1 | 753 |
| 1.96 | 356 |
| 1.14 | 243 |
| 0.36 | 236 |

It was confirmed by the examination that the lower the dissolved oxygen concentration in the water becomes, the shorter the period of time required to cleave the ingot becomes. It was also found that, in a case where the dissolved oxygen concentration is in excess of 1.96 mg/L, the required period of time is shortened to a relatively large degree by a reduction in the dissolved oxygen concentration, whereas, in a case where the dissolved oxygen concentration is equal to or smaller than 1.96 mg/L, the required period of time is shortened to a relatively small degree by a reduction in the dissolved oxygen concentration. In view of the results of the examination and the time and effort taken to deaerate water, it is considered that it is preferable to deaerate the water in which the ultrasonic waves are to be propagated until the dissolved oxygen concentration in the water reaches 2.0 mg/L or lower.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A water refining apparatus for refining water flowing therein, comprising:
a filter for filtering the water to remove solid particles therefrom;
a sterilizing unit disposed downstream of the filter and for irradiating the water with ultraviolet rays to sterilize the water;
an ion exchange filter disposed downstream of the sterilizing unit and for performing an ion exchange on impurity ions contained in the water to remove impurities from the water;
a deaerating unit for deaerating the water; and
a measuring unit disposed downstream of the deaerating unit and for measuring a dissolved oxygen concentration in the water.

2. The water refining apparatus according to claim 1, wherein
the measuring unit measures the dissolved oxygen concentration by referring to an intensity of deep ultraviolet rays that have passed through the water.

3. The water refining apparatus according to claim 2, wherein
the deaerating unit is disposed downstream of the filter and upstream of the sterilizing unit,
the measuring unit is disposed upstream of the ion exchange filter, and
the sterilizing unit and the measuring unit share a deep ultraviolet irradiator.

4. The water refining apparatus according to claim 1, further comprising:
a controller for adjusting operating conditions of the deaerating unit,
wherein, in a case where the dissolved oxygen concentration measured by the measuring unit exceeds a predetermined value, the controller adjusts the operating conditions to reduce the dissolved oxygen concentration.

5. The water refining apparatus according to claim 1, further comprising:
a valve selectively switchable to a forward state in which it introduces the water that has passed through the measuring unit into a forward channel and a reverse state in which it introduces the water that has passed through the measuring unit into a reverse channel for the water going back to the deaerating unit; and
a controller for adjusting the state of the valve,
wherein the controller switches the valve to the reverse state when the dissolved oxygen concentration measured by the measuring unit exceeds a predetermined value and switches the valve to the forward state when the dissolved oxygen concentration measured by the measuring unit is equal to or smaller than the predetermined value.

6. The water refining apparatus according to claim 1, wherein
the deaerating unit and the measuring unit are disposed downstream of the filter and upstream of the sterilizing unit, or downstream of the sterilizing unit and upstream of the ion exchange filter, or downstream of the ion exchange filter.

7. The water refining apparatus according to claim 1,
wherein the deaerating unit includes
a chamber for storing the water therein,
a decompressor for decompressing an inner space of the chamber, and
an ultrasonic oscillator for applying ultrasonic waves to the water that has flowed into the chamber.

8. The water refining apparatus according to claim 7, wherein
the ultrasonic oscillator oscillates ultrasonic waves at a frequency ranging from 0.1 to 1.0 MHz, and
the decompressor decompresses the inner space of the chamber to a pressure of 0.2 atm or lower.

9. The water refining apparatus according to claim 1, wherein
the deaerating unit deaerates the water such that the dissolved oxygen concentration in the water reaches 2.0 mg/L or lower.

10. The water refining apparatus according to claim 1, further comprising:
a first pipe disposed upstream of the filter and the deaerating unit and connectable to a water discharge port of a water utilizing apparatus that utilizes the water to perform a processing operation; and
a second pipe disposed downstream of the ion exchange filter and the measuring unit and connectable to a water supply port of the water utilizing apparatus.

11. The water refining apparatus according to claim 1, further comprising:
a second filter disposed downstream of the ion exchange filter and for filtering the water to remove therefrom solid particles caused by the ion exchange filter; and
a temperature regulating unit disposed downstream of the second filter and for regulating a temperature of the water.

12. The water refining apparatus according to claim 1, further comprising:
a tank disposed upstream of the filter and for storing the water.

13. A method of manufacturing a wafer from an ingot, comprising:
a fragile layer forming step of applying, to an ingot, a laser beam having a wavelength transmittable through the ingot while positioning a focused spot of the laser beam in the ingot at a depth from an end face thereof that corresponds to a thickness of the wafer, thereby forming a fragile layer including modified regions and cracks developed therefrom in the ingot; and
after the fragile layer forming step, a cleaving step of propagating ultrasonic waves to the ingot through water refined by a water refining apparatus and supplied to the end face of the ingot, thereby further developing the cracks to cleave the ingot along the fragile layer,
wherein the water refining apparatus includes
a filter for filtering the water to remove solid particles therefrom,
a sterilizing unit disposed downstream of the filter and for irradiating the water with ultraviolet rays to sterilize the water,
an ion exchange filter disposed downstream of the sterilizing unit and for performing an ion exchange on impurity ions contained in the water to remove impurities from the water,
a deaerating unit for deaerating the water, and
a measuring unit disposed downstream of the deaerating unit for measuring a dissolved oxygen concentration in the water.

14. The method of manufacturing a wafer according to claim 13, wherein
the ingot is made of monocrystalline silicon carbide.

15. The method of manufacturing a wafer according to claim 14, wherein
the end face lies not parallel to a c-plane of the monocrystalline silicon carbide, and
the fragile layer forming step includes
an irradiating step of irradiating the ingot with the laser beam while moving the focused spot of the laser beam and the ingot relatively to each other along a direction parallel to a crossing line along which the c-plane of the monocrystalline silicon carbide and the end face cross each other, and
an indexing step of moving a position where the focused spot of the laser beam is to be formed and the ingot relatively to each other along a direction perpendicular to the crossing line, and
the irradiating step and the indexing step are alternately performed repeatedly in the fragile layer forming step.
